(19) United States
(12) Patent Application Publication
(10) Pub. No.: US 2026/0247913 A1
(43) Pub. Date: Aug. 20, 2026

(54) SIMPLIFIED SWAPPER MODULE DESIGN

(71) Applicant: Applied Materials, Inc., Santa Clara, CA (US)

(72) Inventors: Ralph LINDENBERG, Büdingen-Rinderbügen (DE); Oliver HEIMEL, Wabern (DE)

(21) Appl. No.: 19/056,138

(22) Filed: Feb. 18, 2025

(51) Int. Cl. H01L 21/677; B25J 11/00; H01L 21/687

(52) U.S. Cl. CPC H10P 72/3302; B25J 11/0095; H10P 72/7602; H10P 72/7612

(57) ABSTRACT

In one example, a swapper module includes a housing defining an internal volume, and a swapper at least partially disposed within the internal volume of the housing and actuatable within the housing. The swapper includes a shaft, a first arm coupled to the shaft, and a second arm coupled to the shaft. A first seal plate is disposed at a distal end of the first arm, and a second seal plate is disposed at a distal end of the second arm. An actuator is coupled to the swapper to vertically and rotatably actuate the swapper.

### BACKGROUND

### Field

Embodiments of the present disclosure generally relate to a swapper module and methods of transferring substrates.

### Description of the Related Art

Processing systems are used in the manufacturing of semiconductor devices on substrates. Processing systems have robotic mechanisms that are used to convey substrates between different chambers within the processing system. Conventionally, a substrate is placed in a load lock of the processing system and then may be transferred between multiple robotic mechanisms before being placed into a process chamber that deposits or otherwise forms a layer or feature on the surface of the substrate. Conventional systems suffer from reduced throughput, and excess hardware such as motors.

There is a need in the art for improved substrate transferring.

### SUMMARY

In one embodiment, a swapper module includes a housing defining an internal volume, and a swapper at least partially disposed within the internal volume of the housing and actuatable within the housing. The swapper includes a shaft, a first arm coupled to the shaft, and a second arm coupled to the shaft. A first seal plate is disposed at a distal end of the first arm, and a second seal plate is disposed at a distal end of the second arm. An actuator is coupled to the swapper to vertically and rotatably actuate the swapper.

In another embodiment, a processing system includes a swapper module, comprising: a housing defining an internal volume; a swapper at least partially disposed within the internal volume of the housing and actuatable within the housing, the swapper including: a shaft; a first arm coupled to the shaft; and a second arm coupled to the shaft. A first seal plate is disposed at a distal end of the first arm, and a second seal plate disposed at a distal end of the second arm. An actuator is coupled to the swapper to vertically and rotatably actuate the swapper. A process chamber is coupled to the swapper module above the housing, and a load lock chamber is coupled to the swapper module above the housing and adjacent the process chamber.

In another example, a processing system includes a first swapper module, comprising: a housing defining an internal volume; a first swapper at least partially disposed within the internal volume of the housing and actuatable within the housing. The first swapper includes a shaft; a first arm coupled to the shaft; and a second arm coupled to the shaft. A first seal plate is disposed at a distal end of the first arm, and a second seal plate is disposed at a distal end of the second arm. An actuator is coupled to the first swapper to vertically and rotatably actuate the first swapper. A second swapper is at least partially disposed within the internal volume of the housing and actuatable within the housing, the second swapper including: a shaft; a first arm coupled to the shaft; and a second arm coupled to the shaft; a first seal plate disposed at a distal end of the first arm; a second seal plate disposed at a distal end of the second arm; and an actuator coupled to the at least one swapper to vertically and rotatably actuate the second swapper. The processing system also includes a first process chamber coupled to the housing above the first swapper, a first load lock chamber coupled to the housing above the first swapper, a second process chamber coupled to the housing above the second swapper, and a second load lock chamber coupled to the housing above the second swapper.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, as the disclosure may admit to other equally effective embodiments.

FIG. 1A is a cross-sectional view of a substrate processing system, according to embodiments described herein.

FIG. 1B is a partial cross-sectional view of a substrate processing system, according to embodiments herein.

FIG. 1C is a cross-sectional view of a substrate processing system, according to embodiments described herein.

FIG. 1D is a partial cross-sectional view of a substrate processing system, according to embodiments herein.

FIGS. 2A-2B is a mechanism for pin-less substrate transfer for use in at least some of the substrate processing systems disclosed herein.

FIGS. 3A-C is a cross-sectional view of a substrate swapper module, according to another embodiment herein. FIGS. 3D-3F illustrate partial schematic plan views of a swapper during processing.

FIG. 4 is a perspective view of a substrate processing system, according to embodiments described herein.

FIGS. 5A-B is a plan view of a first and second substrate swapper module, according to embodiments described herein.

FIG. 6A-6D are plan views of substrate processing systems, according to embodiments described herein.

FIG. 7 is a plan view of substrate processing system, according to embodiments described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure generally relates to substrate swapper modules, and methods of using the same. The substrate swapper modules may be used on a cluster tool, which is a system comprising multiple chambers which perform various functions in the electronic device fabrication process.

It should be noted that directional words such as “up,” “down,” “above,” “below,” “vertical,” “horizontal,” and the like are not absolute directions, but relative to an orientation of the chamber, for example, relative to a basis plane of the chamber, which may be a plane defined by a substrate support in the chamber.

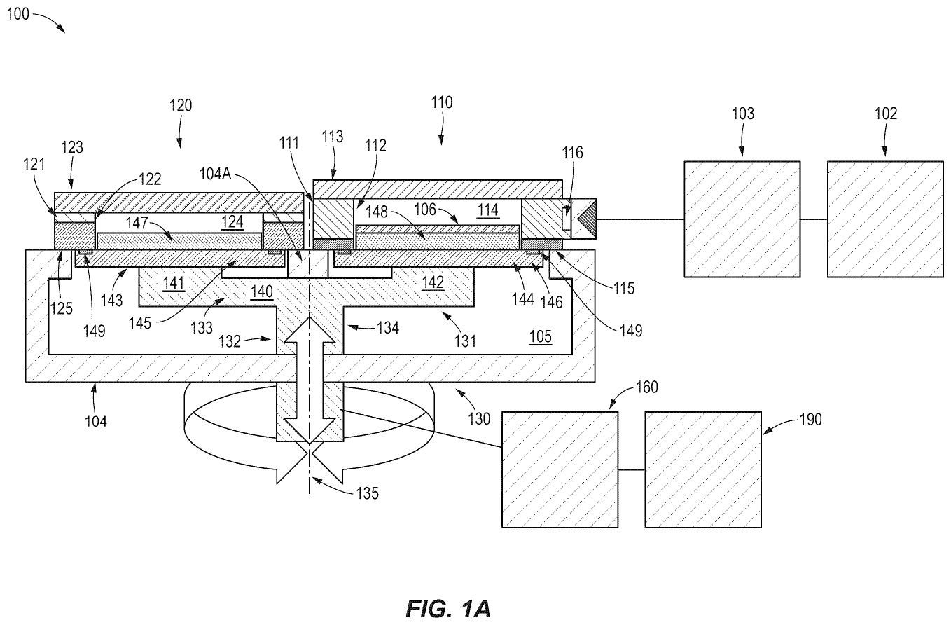

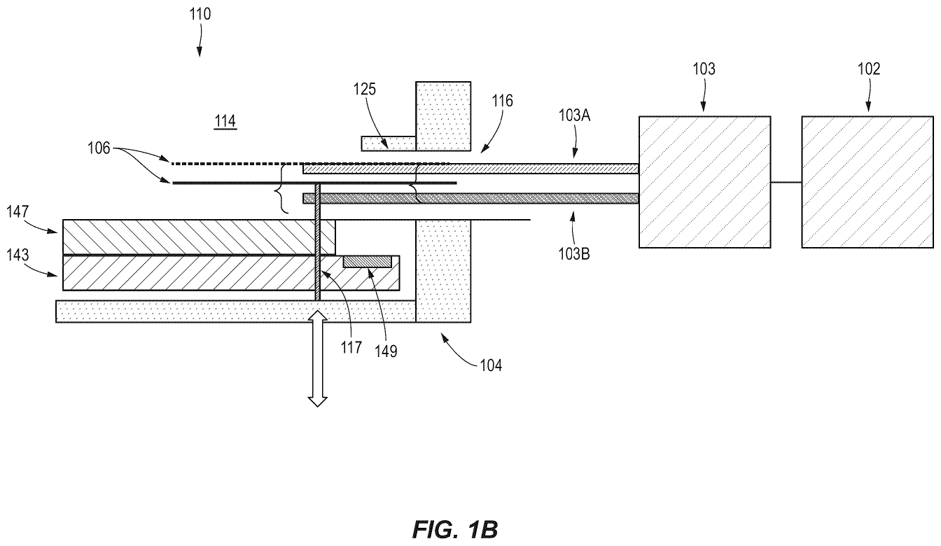

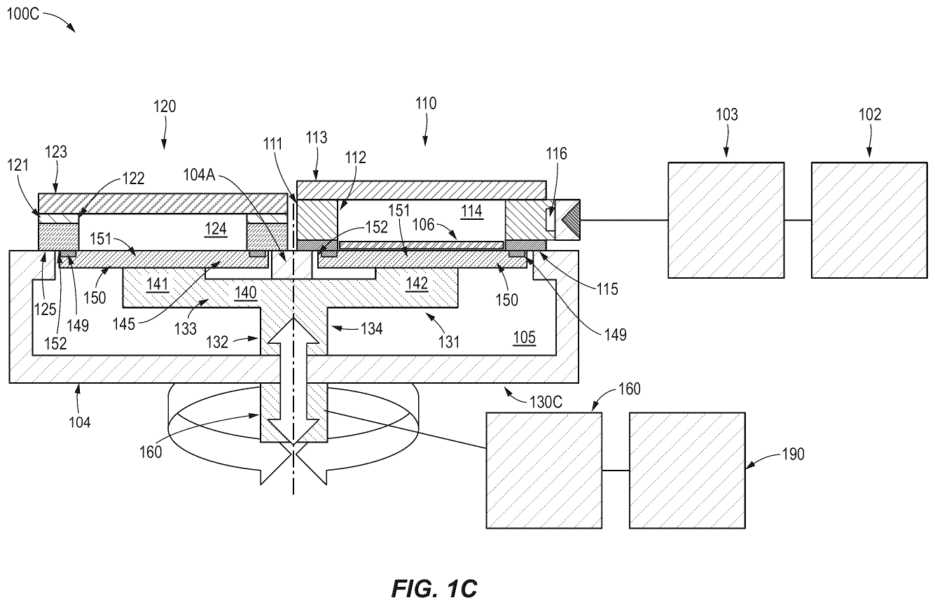

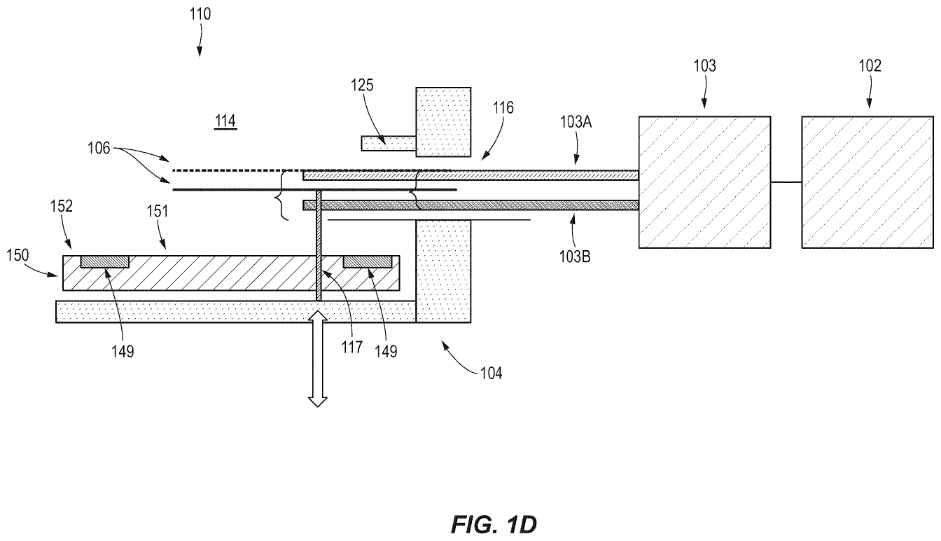

FIG. 1A is a front cross-sectional view of a substrate processing system 100 according to one embodiment of the disclosure. The substrate processing system 100 includes a factory interface 103, at least one load lock chamber 110, at least one process chamber 120, at least one swapper module 130, and a controller 190.

The factory interface 103 is configured to receive one or more front opening unified pods (FOUPs) 102. FOUPs 102 may each be a container having a stationary cassette therein for holding multiple substrates. FOUPs 102 may each have a front opening interface configured to be used with factory interface 103. Factory interface 103 may have a buffer chamber (not shown) and one or more robot assemblies (not shown) configured to transfer substrates via linear, rotational, and/or vertical movement between FOUPs 102 and the load lock chambers 110. Conditioning of a substrate 106 may begin in the factory interface 103. Processes of substrate 106 conditioning may include temperature adjustment, desorption, or electrostatic discharge. The factory interface 103 may have controllable temperature and humidity levels. The temperature and humidity levels of the factory interface 103 may be controlled independently relative to the substrate processing system 100. The temperature and humidity levels may be adjusted to accelerate a process of water level desorption on the substrate 106.

Each load lock chamber 110 includes a chamber body 111. The chamber body 111 includes chamber walls 112 and a chamber lid 113. The chamber lid 113 is disposed on top of the chamber walls 112. The chamber walls 112 and the chamber lid 113 define an internal volume 114 therein. A sealing surface 115 is disposed at the base of the chamber walls 112. The sealing surface 115 may include a metal or ceramic member or interface, having a surface roughness sufficient to facilitate a vacuum seal. Each load lock chamber 110 may further include a slit valve 116. When the slit valve 116 is open, a substrate 106 can be transferred from the factory interface 103 to support members positioned in the load lock chamber 110. In some embodiments, the support members may comprise lift pins 117 (as shown in FIG. 1B). When the slit valve 116 is closed, the interior of the load lock chamber 110 is isolated from the factory interface 103. Thus, the load lock chamber 110 provides a vacuum interface between the factory interface 103 (e.g., front-end environment) and the remainder of the substrate processing system 100. In certain embodiments, the substrate processing system 100 may include a plurality of load lock chambers 110.

Each process chamber 120 includes a chamber body 121. The chamber body 121 includes chamber walls 122 and a chamber lid 123. The chamber lid 123 is disposed on top of the chamber walls 122. The chamber walls 122 and the chamber lid 123 define an internal volume 124 therein. A sealing surface 125 is disposed at the base of the chamber walls 122. The sealing surface 125 may include a metal or ceramic member or interface, having a surface roughness sufficient to facilitate a vacuum seal. The process chambers 120 may perform any number of processes such as preclean, PVD, CVD, ALD, decoupled plasma nitridation (DPN), rapid thermal processing (RTP), and etching. Exemplary process chamber(s) 120 are commercially available from APPLIED MATERIALS, Inc. of Santa Clara, Calif. Chambers from other manufacturers may also be used in the substrate processing system 100. In certain embodiments, the substrate processing system 100 may include a plurality of process chambers 120.

The swapper module 130 includes a housing 104. The housing 104 defines an internal volume 105 therein. The swapper 131 is partially disposed in the internal volume 105. The swapper 131 is disposed beneath the load lock chamber 110 and the process chamber 120, so as to access the load lock chamber 110 and the process chamber 120 from the undersides thereof. The housing 104 engages the sealing surface 115 and the sealing surface 125 to form a seal. Thus, the sealing surfaces 115, 125 seal with both the housing 104 and the swapper 131. The housing seal may allow for vacuum sealing of the internal volume 105 to reduce exposure of the internal volume 105 to environments outside the housing 104. The substrates 106 may pass through the internal volume 105 between the load lock chamber 110 and the process chamber 120. A processing system 100 having a plurality of load lock chambers 110, a plurality of process chambers 120, or a combination thereof, may have a singular shared internal volume 105. A processing system 100 having a plurality of load lock chambers 110, a plurality of process chambers 120, or a combination thereof, may have multiple separated internal volumes 105. In some embodiments, separated internal volumes 105 may be used for, but not limited to, particle control, heating control, vacuum separation, and the like.

Each swapper module 130 includes at least one swapper 131. The swapper 131 includes a body 132 that includes an upper portion 133 and a shaft 134 that extends downward from the upper portion 133. The upper portion 133 includes an arm assembly 140. The shaft 134 extends downward through the housing 104 and is coupled to an actuator 160 for actuating the shaft 134, rotationally and/or vertically. The housing 104 is disposed around the shaft 134 allowing for vacuum sealing of the internal volume 105 to stop exposure of the internal volume 105 to atmosphere outside the housing 104. To facilitate sealing, a bellows or other seal may be utilized. The housing 104 further includes an inner housing member 104A disposed between the load lock chamber 110 and the process chamber 120, as to allow vacuum sealing of the internal volume 105. The housing member 104A includes a rotary bearing disposed thereon, on a distal end inside the internal volume 105. The upper portion 133 of the swapper 131 engages the rotary bearing of the inner housing member 104A upon upwards actuation of the swapper 131.

The arm assembly 140 includes a first arm 141 (e.g., left arm) and a second arm 142 (e.g., right arm) extending outward from the shaft 134. In some embodiments, the arm assembly 140 may include more than two arms. In some embodiments, the arm assembly 140 includes a third arm. The arms 141, 142 are rotated by the actuator 160 around a central axis 135 of the shaft 134. The arms 141, 142 may be located in a transfer position at a transfer height where each of the arms 141, 142 is located under either the load lock chamber 110 or under the process chamber 120. FIG. 1A shows the first arm 141 in an engaged position, with the first arm 141 positioned under the process chamber 120, while the second arm 142 is shown in an engaged position under the load lock chamber 110.

The arms 141, 142 may further include seal plates 143, 144 disposed at distal ends thereof. The seal plates 143, 144 further include heater plates 147, 148 disposed thereon. The seal plates 143, 144 extend out radially past the heater plates 147, 148 thereby forming seal plate shelves 145, 146 that are unobscured by the heater plates 147, 148. The seal plate shelves 145, 146 provide sealing surfaces to engage sealing surfaces of the process chamber 120 and/or the load lock chamber 110. The seal plate shelves 145, 146 further comprise sealing members 149 coupled to or formed in an upper surface of the seal plate shelves 145, 146. The sealing members 149 may be physical sealing members. The sealing members 149 may substantially comprise an elastomer seal such as an o-ring. The sealing members 149 may be an air curtain, or a purge gas curtain. The sealing members 149 may circumscribe the heater plates 147, 148. The heater plates 147, 148 are configured to support a substrate 106 thereon. In some embodiments, the seal plates 143, 144 and the heater plates 147, 148 may include a plurality of openings to allow a corresponding lift pin 117 (as shown in FIG. 1B) of the load lock chamber 110 to access the underside of the substrate 106 to facilitate loading or unloading of the substrate 106 to/from the heater plate 147, 148.

The swapper module 130 further includes an actuator 160. In some embodiments, the actuator 160 may comprise a stepper motor, brush or brushless motor, linear actuator, or other motion driving device. One actuator 160 may actuate more than one swapper module 130 and/or more than one swapper 131, simultaneously or consecutively. The swapper 131 is actuatable in a vertical direction by the actuator 160 such that the swapper 131 is capable of retraction downward into the internal volume 105, and actuation upward towards the load lock chamber 110 and process chamber 120. Once retracted to the transfer position at the transfer height, the swapper 131 may be rotated around a central axis 135 of the swapper 131. Upon rotation, such as 180 degrees in one example, the arms 141, 142 are moved to exchange positions. In exchange positions, the first arm 141, which was located in a position beneath the process chamber 120, is moved to a position beneath the load lock chamber 110, and the second arm 142, which was located in a position beneath the load lock chamber 110, is moved to a position beneath the process chamber 120. While 180 degrees is used as an example, it is to be noted that other angular rotations are contemplated. In one example, the degrees of angular rotation are equal to 360 degrees divided by the number of arms of the swapper 131. In another example, the degrees of angular rotation are equal to 360 degrees divided by the total combined number of load lock chambers 110 and process chambers 120. In another example, swapping occurs via linear rather than rotational motion. To facilitate linear motion, the first seal plate 144 and the second seal plate 145 are vertically offset each other such that the actuator may actuate the first seal plate 144 and the second seal plate 145 to exchange positions. A gear may be used to drive the seals plates along a linear axis, simultaneously in opposite directions. Thus, the first seal plate 144 passes over the second seal plate 145 (or vice versa) along axis facilitating an exchange of position.

After the swapper 131 is rotated within the internal volume 105 and the first arm 141 and the second arm 142 are in exchange (e.g., swap) positions, the swapper 131 may be actuated upwards towards the load lock chamber 110 and the process chamber 120 using the actuator 160. The swapper 131 may be actuated such that the first arm 141 and the second arm 142 are actuated simultaneously. The swapper 131 may be actuated upwards until the swapper 131 contacts the load lock chamber 110 and the process chamber 120. In the actuated position, the seal plate shelves 145, 146 may contact the sealing surface 115 and the sealing surface 125, such that the sealing members 149 contact the sealing surface 115, 125. Once contact has been made between the sealing member 149 and the sealing surfaces 115, 125, a vacuum seal may be formed within the load lock chamber 110 and within the process chamber 120. The vacuum seal allows the pressure in each chamber to be reduced using an exhaust pump. The pressure of the internal volume 114 of the load lock chamber 110 may be manipulated for achieving a predetermined substrate transferring environment. The pressure of the internal volume 124 of the process chamber 120 may be manipulated for achieving a predetermined processing environment. The pressure of the internal volume 114 and the pressure of the internal volume 124 may differ from each other and may differ from the pressure of the internal volume 105.

In some embodiments, the load lock chamber 110 may be actuated upwards, detaching the chamber body 111 from the housing 104. The load lock chamber 110 may be actuated upwards simultaneously with the swapper 131. The load lock chamber 110 may be actuated upwards before or after the swapper 131 is actuated upwards. The load lock chamber 110 and the swapper 131 may be actuated upward the same distance or different distances. After the load lock chamber 110 has been actuated upwards to elevate the chamber body 111 from the housing 104, the substrate 106 may be accessed by the factory interface 103.

The controller 190 can be in communication with the actuator 160 to control the position of the arms 141, 142 of the swappers 131, as well as other aspects of the substrate processing system 100.

The controller 190 may include a programmable central processing unit (CPU) which is operable with a memory (e.g., non-transitory computer readable medium and/or non-volatile memory) and support circuits. The support circuits are coupled to the CPU and includes cache, clock circuits, input/output subsystems, power supplies, and the like, and combinations thereof coupled to the various components of the substrate processing system 100, to facilitate control of the substrate processing system 100. For example, in one or more embodiments the CPU is one of any form of general purpose computer processor used in an industrial setting, such as a programmable logic controller (PLC), for controlling various polishing system components and sub-processors. The memory, coupled to the CPU, is non-transitory and is one or more of readily available memory such as random access memory (RAM), read only memory (ROM), floppy disk drive, hard disk, or any other form of digital storage, local or remote.

Herein, the memory is in the form of a computer-readable storage media containing instructions (e.g., non-volatile memory), that when executed by the CPU, facilitates the operation of the substrate processing system 100. The instructions in the memory are in the form of a program product such as a program that implements the methods of the present disclosure (e.g., middleware application, equipment software application, etc.). The program code may conform to any one of a number of different programming languages. In one or more embodiments, the disclosure may be implemented as a program product stored on computer-readable storage media for use with a computer system. The program(s) of the program product define functions of the embodiments (including the methods and operations described herein).

Illustrative computer-readable storage media include, but are not limited to: (i) non-writable storage media (e.g., read-only memory devices within a computer such as CD-ROM disks readable by a CD-ROM drive, flash memory,

ROM chips or any type of solid-state non-volatile semiconductor memory) on which information is permanently stored; and (ii) writable storage media (e.g., floppy disks within a diskette drive or hard-disk drive or any type of solid-state random access semiconductor memory) on which alterable information is stored. Such computer-readable storage media, when carrying computer-readable instructions that direct the functions of the methods described herein, are embodiments of the present disclosure.

FIG. 1B illustrates enhanced partial cross-section view of the substrate processing system 100. As shown in FIG. 1B, the seal plate 143 and heater plate 147 are in a retracted position within the housing 104. The factory interface 103 further includes a setting arm 103A and a retrieving arm 103B. After the factory interface 103 has finished pre-processing the substrate 106, the slit valve 116 of the load lock chamber 110 may open and the setting arm 103A may actuate into the internal volume 114 with the substrate 106 thereon. Thereafter, the lift pins 117 engages the substrate 106 and lowers the substrate 106 onto the heater plate 147. After the substrate 106 has been processed (e.g., transferred into the process chamber 120, and then transferred back), the lift pins 117 are actuated upwards, lifting the substrate 106 into retrieval position wherein the retrieving arm 103B of the factory interface may enter the internal volume 114 through the slit valve 116 and engage the substrate 106. The retrieving arm 103B may then retract into the factory interface with the substrate 106 disposed thereon.

FIG. 1C illustrates a partial cross-section view of a substrate processing system 100C comprising a swapper module 130C that may be substituted for the swapper module 130 of the substrate processing system 100. The swapper module 130C has similar components to the swapper module 130 as indicated by the reference signs without reciting the description of these components of the swapper module 130 for brevity.

Rather than including a separate seal plate 143 and heater plate 147, the cover plates 150 provide both the sealing capabilities of seal plate 143 and heating capabilities of heater plate 147, in a single (e.g., monolithic) body. Cover plates 150 include an inner surface 151 and an outer surface 152 surrounding the inner surface 151, which together define an upper surface of the cover plates 150. The inner surface 151 supports a substrate 106 thereon, while the outer surface 152 does not make contact with the substrate 106, but instead remains uncovered to facilitate sealing with the load lock 110 or the process chamber 120. The inner surface 151 may be substantially featured (e.g., include support features such as bumps, channels, mesas, or grooves) and include openings for vacuum/purge gas and/or lift pins. One or more heating elements may optionally be embedded within the covers plates 150 sealing member 149 thereon. In some embodiments, the sealing member may be an elastomer secured in a groove of the outer surface 152.

Upon actuation of the swapper 131 upwards, the outer surface 152 and the sealing member 149 engage the sealing surfaces 115, 125 such that a vacuum seal may be formed within the internal volume 114, 124. The inner surface 151 and the substrate 106 are disposed within the internal volume 114, 124.

FIG. 1D illustrates enhanced partial cross-section view of the substrate processing system 100C. As shown in FIG. 1D, the cover plate 150 is in a retracted position within the housing 104. After the factory interface 103 has finished pre-processing the substrate 106, the slit valve 116 of the load lock chamber 110 may open and the setting arm 103A may actuate into the internal volume 114 with the substrate 106 thereon. Thereafter, the lift pins 117 engage the substrate 106 and lower the substrate 106 onto the cover plate 150. After the substrate 106 has been processed (e.g., transferred into the process chamber 120, and then transferred back), the lift pins 117 are actuated upwards, lifting the substrate 106 into retrieval position wherein the retrieving arm 103B of the factory interface may enter the internal volume 114 through the slit valve 116 and engage the substrate 106. The retrieving arm 103B may then retract into the factory interface with the substrate 106 disposed thereon.

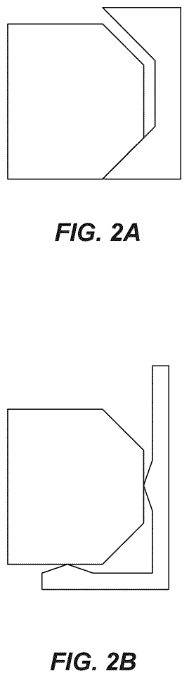

FIGS. 2A-B illustrates a mechanism for pin-less wafer transfer as contemplated in the substrate processing system 100. FIGS. 2A-B are a detailed view of an area of either or both setting arm 103A or retrieving arm 103B. FIGS. 2A-B illustrate substrate 106 engaging a surface of arms 103A, 103B. In this way, substrate 106 is supported by arms 103A and 103B during the setting and retrieval functions, replacing the need for a support member, such as lift pins 117, to transfer the substrate 106 from the factory interface 103.

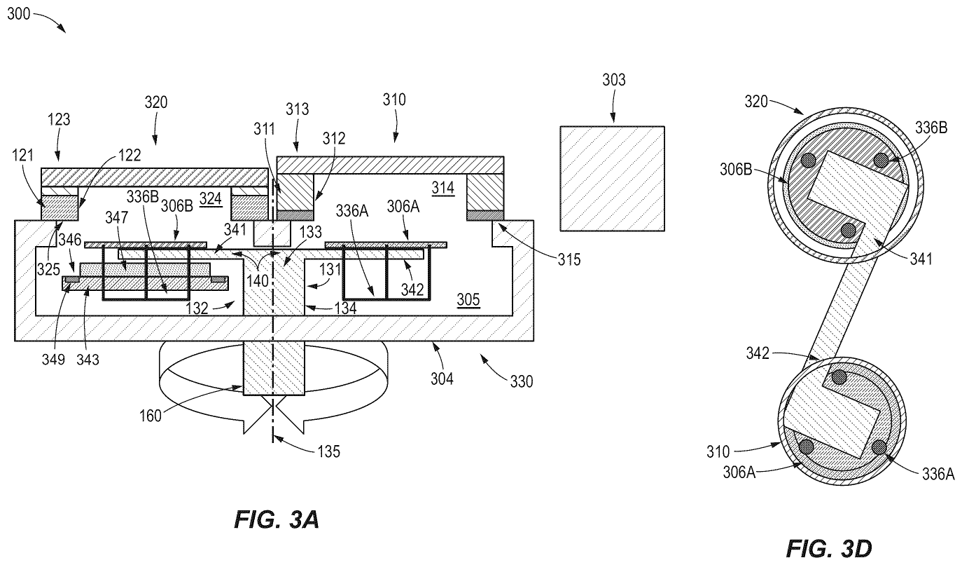

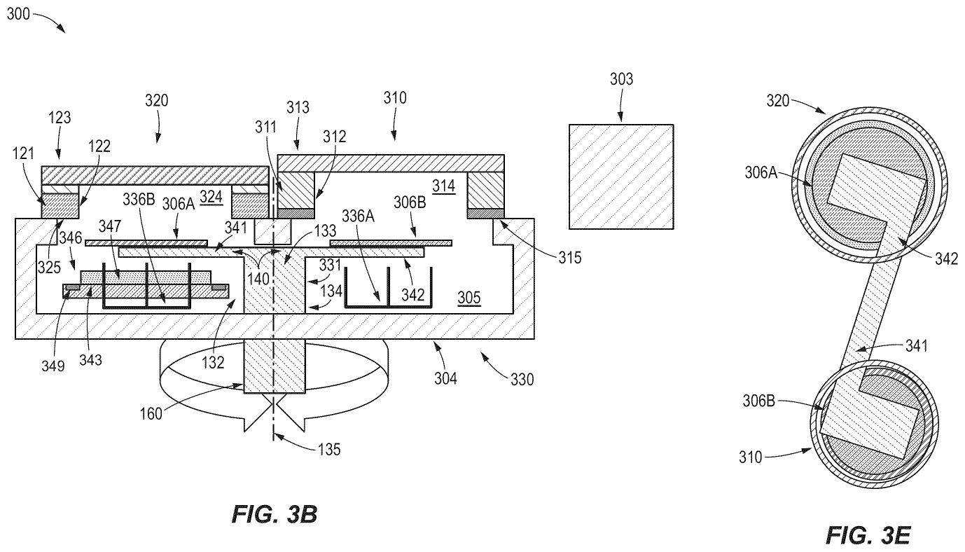

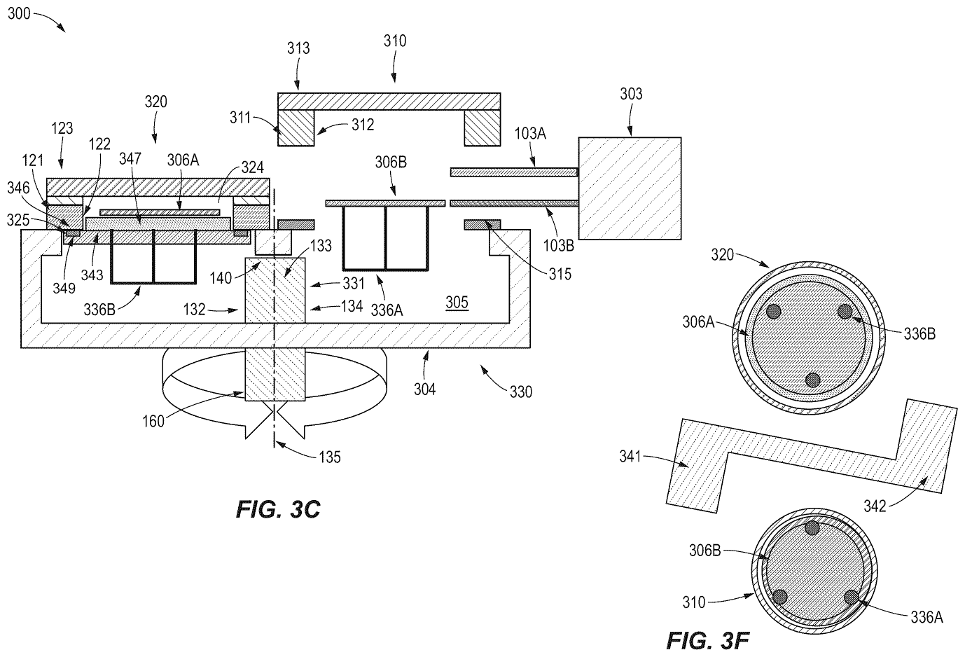

FIGS. 3A-C illustrate a front cross-sectional view of a substrate processing system 300 including a swapper module 330 that may be substitute for the swapper module 130 of the substrate processing system 100. FIGS. 3D-3E illustrate partial schematic plan views of a swapper during processing. The swapper module 330 has similar components as the swapper module 130 as indicated by the reference signs without reciting the description of these components of the swapper module 130 for brevity.

Referring now to FIG. 3A, the swapper module 330 may further comprise a lift pin array 336A and 336B. The first arm 341, the seal plate 343, and the heater plate 347 include a plurality of openings to allow corresponding lift pin array 336A to access the underside of the substrate 306B. The substrate 306B may then be actuated upward into a processing position within the process chamber 320. The second arm 342 includes a plurality of openings to allow corresponding lift pin array 336A to access the underside of the substrate 306A. The substrate 306A may then be actuated upwards towards the load lock chamber 310 to be accessed by the setting arm 103A or the retrieving arm 103B of the factory interface 103. The setting arm 103A may be used to align the center of the substrate 306A in a desired position within the load lock chamber 310.

Referring now to FIG. 3B, the lift pin arrays 336A-B may disengage the substrates 306A-B through retraction into the internal volume 305. Once retracted, the lift pin arrays 336A, 336B place substrates 306A, 306B on the swapper 331, and recede below the swapper 331. The swapper 331 may then be rotated around a central axis 135 of the swapper 331. Upon rotation, the arms 341, 342 are moved to exchange positions. In exchange positions, the first arm 341, which was located in a position beneath the process chamber 320, is moved to a position beneath the load lock chamber 310, and the second arm 342, which was located in a position beneath the load lock chamber 310, is moved to a position beneath the process chamber 320. Additionally, in exchange position, substrates 306A, 306B have exchanged positions such that substrate 306A is disposed beneath process chamber 320 and substrate 306B is disposed beneath load lock chamber 310. After the arms 341, 342 have rotated to exchange positions, the lift pin arrays 336A, 336B are actuated upwards to engage the underside of the substrates 306A, 306B. The arms may be further rotated to a non-exchange position, for example 90 degrees, wherein the arms 341, 342 are not located under either the load lock chamber 310 or the process chamber 320. While 90 degrees is used as an example, it is to be noted that other angular rotations are contemplated. Any degree of rotation wherein the arms 341, 342 are not located under either the load lock chamber 310 or the process chamber 320 is suitable. In one example, the degrees of angular rotation are about equal to between 45 degrees and 135 degrees. In another example, the degrees of angular rotation are about equal to between 225 degrees and 315 degrees.

Referring to FIG. 3C, after the arms 341, 342 have entered a non-exchange position. In non-exchange position, the arms 341, 342 are not located under either the load lock chamber 310 or the process chamber 320. In non-exchange position, the lift pin arrays 336A-B may be further actuated upwards. Upon actuation, lift pin array 336B engages the seal plate 343, the heater plate 347, and the substrate 306A. Lift pin array 336B then simultaneously lifts the seal plate 343, the heater plate 347, and the substrate 306B upwards toward the process chamber 320, into a processing position. In the processing position, the substrate 306B is located within the internal volume 324, and the seal plate shelf 346 contacts the sealing surface 325, such that the sealing member 349 contacts the sealing surface 325. The sealing members 349 may be physical sealing members. The sealing members 349 may substantially comprise an elastomer seal such as an o-ring. The sealing members 349 may be an air curtain, or a purge gas curtain. Once contact has been made between the sealing member 349 and the sealing surfaces 325, a vacuum seal may be formed within the load the process chamber 320. The vacuum seal allows the pressure in each chamber to be reduced using an exhaust pump. The pressure of the internal volume 324 of the process chamber 320 may be manipulated for achieving a predetermined processing environment. The pressure of the internal volume 314 and the pressure of the internal volume 324 may differ from each other and may differ from the pressure of the internal volume 305.

The lift pin array 336A may be actuated upward to lift the substrate 306A into the load lock chamber 310. The load lock chamber 310 does not include a slit valve; rather, the chamber walls 312 may disengage a sealing surface 315 such that the chamber body 313 may be actuated upwards above the housing 304. Upon actuation of lift pin array 336A, both the lift pin array 336A and the load lock chamber 310 are lifted upwards, either simultaneously or consecutively. The lift pin array 336A and the load lock chamber 310 may be actuated upward the same distance or different distances. After the load lock chamber 310 has been actuated upwards to elevate the chamber body 311 from the housing 304, the substrate 306A may be accessed by a setting arm 103A or a retrieving arm 103B of the factory interface 303.

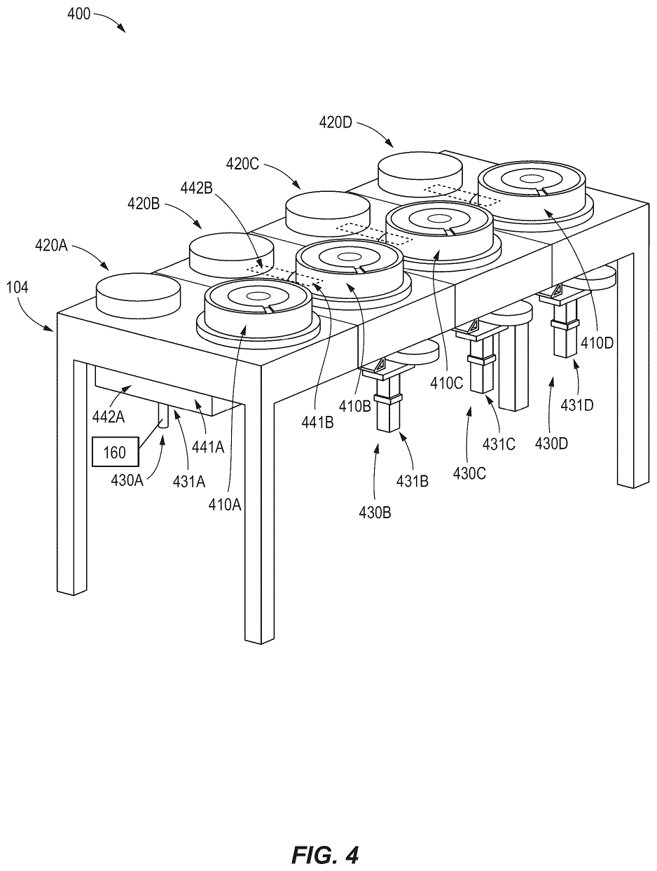

FIG. 4 illustrates a substrate processing system 400 according to some embodiments that includes four or more pairs of load lock chambers 410A-D, process chambers 420A-D, and swapper modules 430A-D. In some embodiments, the substrate processing system 400 includes one swapper module 430A-D corresponding to each pair of load lock chambers 410A-D and process chambers 420A-D, each swapper module 430A-D disposed beneath each pair of load lock chambers 410A-D and process chambers 420A-D. In one example, a single actuator 160 is used to operate all swappers 431A-D, such as four or more swappers 431A-D. In other examples, each swapper 431A-D may have its own respective actuator 160. For example, the substrate processing system 400 may have four swappers 431A-D driven by the same actuator 160. Operating the swappers 431A-D with the same actuator 160 allows all swappers 431A-D to be moved in a synchronous fashion. In some embodiments, each swapper module 430A-D is disposed within the same housing 104 such that every swapper module 430A-D shares one internal volume 114. In some embodiments, the swappers 431A-D are arranged as shown where the arms of one swapper 431A move synchronously with the corresponding arms of the other swapper 431B. In some embodiments, the swappers 431A-D are both vertically and horizontally offset to one another. For example, one swapper 431A may have both arms 441A, 442A at a height above or below the arms 441B, 442B of swapper 431B. The offset allows the swappers 431A-B to rotate synchronously without the arms 441A, 442A of a first swapper 431A to contact the arms 441B, 442B of a second swapper 431B. Each swapper 431A-D may be at a different vertical and/or horizontal offset, or, each swapper 431A-D that is within a radial distance of one another such that their corresponding arms 441A-D, 442A-D that would make contact in a neutral position may be at different horizontal and/or vertical offsets to avoid contact.

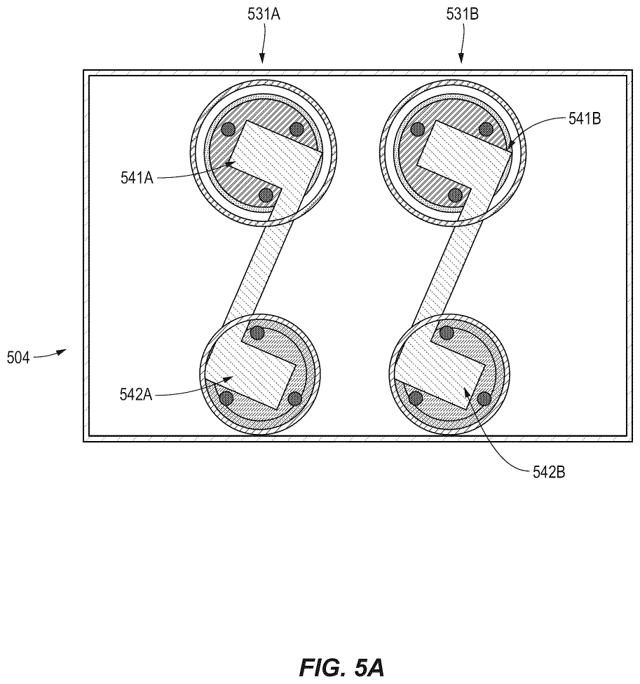

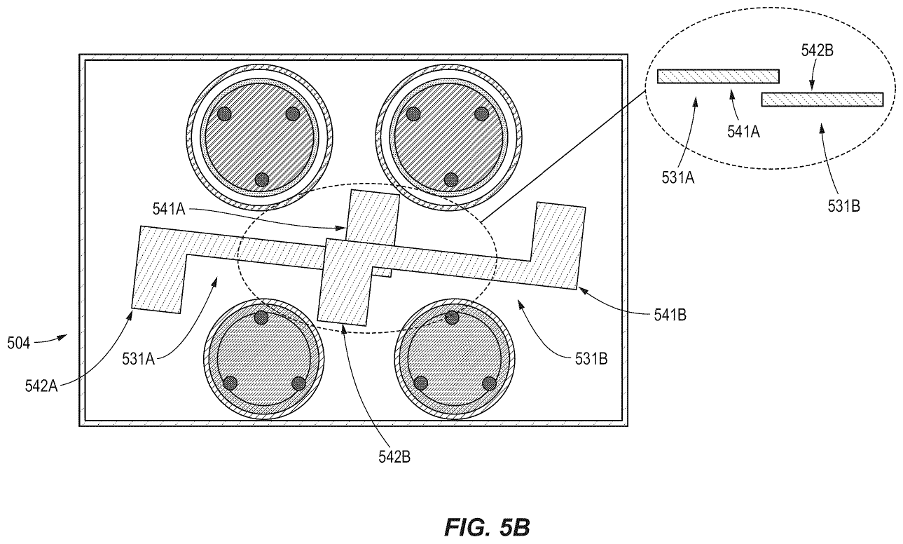

FIG. 5 illustrates a first swapper 531A and a second swapper 531B, comprising first arms 541A, 541B and second arms 542A, 542B, horizontally and vertically offset one another. The first swapper 531A and the second swapper 531B may be the swappers as illustrated in FIG. 4. The rotational path of the first swapper 531A and the rotational path of second swapper 531B overlap each other. The first swapper 531A is at a different height than the second swapper 531B such that when the swappers 531A-B are in a non-exchange position after rotation, the first swapper 531A does not make contact with the second swapper 531B. FIG. 5 additionally shows an enhanced view of the first swapper 531A horizontally and vertically offset the second swapper 531B, the swappers 531A, 531B in a non-exchange position wherein a first arm 541A of the first swapper 531A is located underneath a first arm 541B of the second swapper 531A.

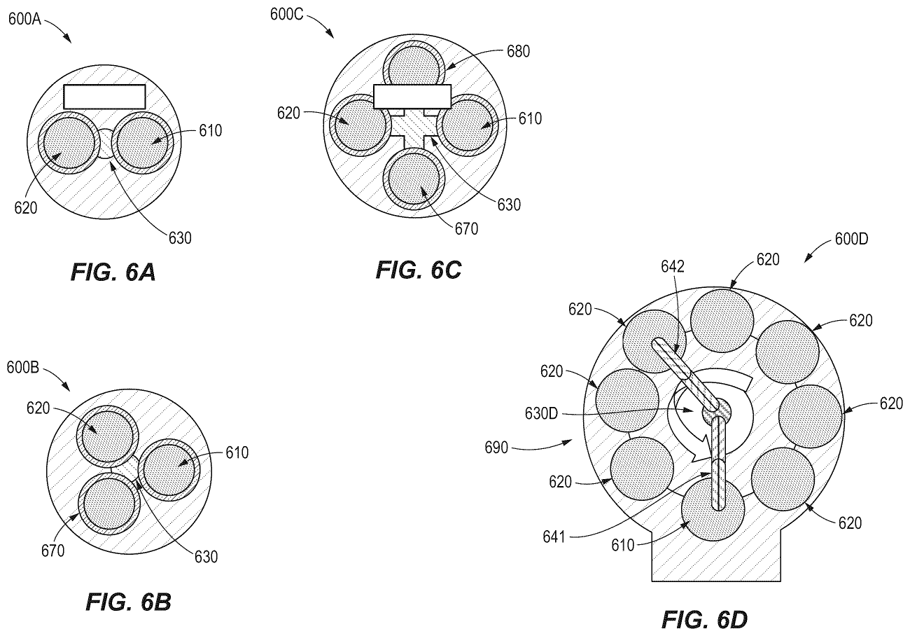

FIG. 6A-6D illustrate a top-down view of substrate processing systems 600A-D according to some embodiments. FIG. 6A illustrates a top-down view of a substrate processing system 600A according to some embodiments that includes one load lock chamber 610, one process chamber 620, and one swapper module 630. FIG. 6B illustrates a top-down view of a substrate processing system 600B according to some embodiments, the substrate processing system of 600B including the elements of substrate processing system 600A, and an additional heating chamber 670. In such an example, a swapper module of the substrate processing system 600B may include three arms configured to rotation through three positions, each spaced 120 degrees from one another. FIG. 6C illustrates a top-down view of a substrate processing system 600C according to some embodiments, the substrate processing system of 600C including the elements of substrate processing system 600B, and an additional non-heating chamber 680. In such an example, a swapper module of the substrate processing system 600C may include four arms configured to rotation through three positions, each spaced 90 degrees from one another.

FIG. 6D illustrates a circular configuration of substrate processing system 600D, including a plurality of chambers 690 consisting of at least one load lock chamber 610, and a plurality of process chambers 620. A swapper module 630 is disposed within the plurality of chambers 690. The swapper module 630 further includes a first arm 641 and a second arm 642 independently operable of each other such that the first arm 641 and the second arm 642 may or may not move in synchronization with each other. Thus, the swapper module 630D is capable of switching a substrate 106 from any chamber of the plurality of chambers 690 into any other chamber of the plurality of chambers 690.

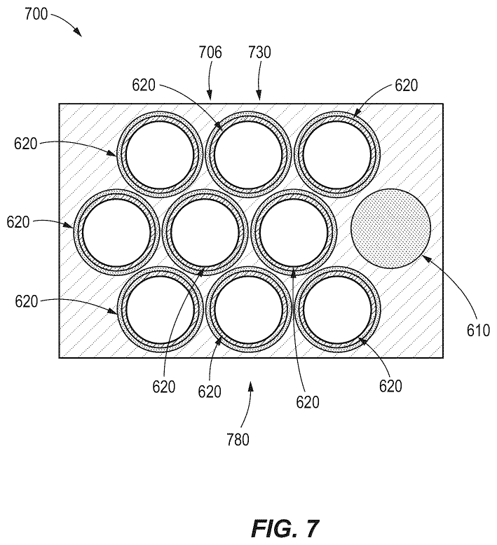

FIG. 7 illustrates a top-down view of substrate processing system 700 according to some embodiments. The substrate processing system 700 has similar components as the substrate processing system 600D as indicated by the reference signs without reciting the description of these components of the substrate processing system 600D for brevity. In some embodiments, the substrate processing system 700 may have a square or rectangular layout within a fabricator. The substrate 106 is transferred beneath a plurality of chambers 780 by a swapper module 730. The swapper module 730 may actuate the substrate 706 upwards into any of the plurality of chambers 780. In such an example, the swapper need not necessary move in a linearly or circular/rotational movement only. Other degrees of movement may be employed to expand the layout of a substrate processing system.

Throughout substrate processing, the substrate 106 is transferred between different environments. For example, the substrate 106 may be transferred from an ambient environment outside the substrate processing system 100 into the substrate processing system 100. Inside the substrate processing system, the substrate 106 may be transferred between FOUPs 102, factory interface 103, load lock chamber 110, internal volume 105, and process chamber 120. Each environment may have a different pressure level from the other environments. For example, the pressure of the ambient environment outside the substrate processing system 100 may be different from the pressure within the processing system 100, and may be different from the pressure of any chamber located therein. The pressure levels between each environment may be manipulated to facilitate a processing of the substrate 106 therein.

In some embodiments, the housing 104 forms a seal around the load lock chamber 110, the process chamber 120, and the swapper module 130 to form one environment. In this way, this environment of the internal volume 105, the internal volume 114 of the load lock chamber 110 and the internal volume 124 of the process chamber 120 may be isolated from an environment outside the substrate processing system 100. In some embodiments, the pressure within the internal volume 105 is similar to the pressure of the internal volume 114 of the load lock chamber 110 and the pressure of the internal volume 124 of the process chamber 120. In this way, the pressure of the internal volume 105, internal volume 114 of the load lock chamber 110, and internal volume 124 of the process chamber 120 may be selectively in fluid communication with each other. Rather than independently adjusting the pressure within the internal volume 105, the internal volume 114 of the load lock chamber 110, and the internal volume 124 of the process chamber 120 when the substrate 106 enters each chamber, only the pressure of the internal volume 124 of the process chamber 120 need be manipulated to reflect process conditions. In some embodiments where the substrate processing system 100 includes multiple internal volumes 105, the pressure of each internal volume 105 and the chambers 110, 120 therein may be manipulated independently from the other internal volumes 105 of the substrate processing system 100.

In some embodiments, as the substrate 106 enters the substrate processing system 100, the setting arm 103A places the substrate 106 into the load lock chamber 110. The substrate 106 is received in the load lock chamber 110 on the heater plate 147 or the cover plate 150. The setting arm 103A is configured to align the substrate 106 onto the heater plate 147 or cover plate 150 in an appropriate processing position. Once disposed on the heater plate 147 or cover plate 150, the substrate 106 may be transferred by the swapper module 130 to the processing chamber 120 to be processed. Rather than using a first setting arm to set and align the substrate 106 within the load lock chamber 110 and then using a second setting arm to set and align the substrate 106 within the process chamber 120, the setting arm 103A need only place and align the substrate 106 in a processing position once. By only having one placing and aligning step, the efficiency of processing the substrate 106 is increased. Additionally, by having the swapper module 130 vertically actuatable such that the substrate 106 may be actuated into the processing chamber 120, the need for a slit valve on the processing chamber is eliminated.

Any one or more components of the substrate processing system and/or swapper module may be integrally formed together, directly coupled together, and/or indirectly coupled together and are not limited to the specific arrangement of components illustrated in FIG. 1A-7. Any one or more of the components, embodiments, or operations of the substrate processing system and/or swapper module may be combined in whole or part with any other components, embodiments, or steps of the substrate processing system and/or swapper module.

While the foregoing is directed to embodiments of the present disclosure, other and further embodiments of the disclosure may be devised without departing from the basic scope thereof, and the scope thereof is determined by the claims that follow.

What is claimed is:

1. A swapper module, comprising:
a housing defining an internal volume;
a swapper at least partially disposed within the internal volume of the housing and actuatable within the housing, the swapper including:
a shaft;
a first arm coupled to the shaft; and
a second arm coupled to the shaft;
a first seal plate disposed at a distal end of the first arm;
a second seal plate disposed at a distal end of the second arm; and
an actuator coupled to the swapper to vertically and rotatably actuate the swapper.

2. The swapper module of claim 1, further comprising a first heater plate disposed on the first seal plate.

3. The swapper module of claim 2, further comprising a second heater plate disposed on the second seal plate.

4. The swapper module of claim 3, wherein the first seal plate further comprises a first sealing member circumscribing the first heater plate.

5. The swapper module of claim 4, wherein the second seal plate further comprises a second sealing member circumscribing the second heater plate.

6. The swapper module of claim 1, wherein the actuator vertically actuates and rotatably actuates the first arm simultaneously with the second arm.

7. The swapper module of claim 1, further comprising a first set of lift pins disposed within the housing for engaging a first substrate supported on the first arm, and a second set of lift pins disposed within the housing for engaging a second substrate supported on the second arm.

8. A processing system, comprising:
a swapper module, comprising:
a housing defining an internal volume;
a swapper at least partially disposed within the internal volume of the housing and actuatable within the housing, the swapper including:
a shaft;
a first arm coupled to the shaft; and
a second arm coupled to the shaft; and
an actuator coupled to the swapper to vertically and rotatably actuate the swapper;
a process chamber coupled to the swapper module above the housing;
a first seal plate disposed in the housing beneath the process chamber, the first seal plate vertically actuatable towards the process chamber; and
a load lock chamber coupled to the swapper module above the housing and adjacent the process chamber.

9. The processing system of claim 8, wherein the load lock chamber comprises a slit valve, and the process chamber is slit-valve-free.

10. The processing system of claim 9, wherein the load lock chamber includes a vertically actuatable lid for ingress and egress of a substrate.

11. The processing system of claim 10, wherein the swapper module includes a first set of lift pins for actuating a substrate within the load lock chamber for ingress and egress of the substrate.

12. The processing system of claim 11, wherein the load lock chamber comprises a body having a sealing surface at a lower end thereof.

13. The processing system of claim 12, wherein the sealing surface disengages from the body of the load lock chamber upon vertical actuation of the vertically actuatable lid.

14. The processing system of claim 8, wherein the internal volume of the swapper module is selectively in fluid communication with an internal volume of the load lock chamber and an internal volume of the process chamber upon vertical actuation of the swapper.

15. The processing system of claim 8, wherein the swapper module further comprises a third arm coupled to the shaft.

16. A processing system, comprising:
a first swapper module, comprising:
a housing defining an internal volume;
a first swapper at least partially disposed within the internal volume of the housing and actuatable within the housing, the first swapper including:
a shaft;
a first arm coupled to the shaft; and
a second arm coupled to the shaft; and
an actuator coupled to the first swapper to vertically and rotatably actuate the first swapper;
a second swapper at least partially disposed within the internal volume of the housing and actuatable within the housing, the second swapper including:
a shaft;
a first arm coupled to the shaft; and
a second arm coupled to the shaft; and
an actuator coupled to the second swapper to vertically and rotatably actuate the second swapper;
a first process chamber coupled to the housing above the first swapper;
a first seal plate disposed in the housing beneath the first process chamber the first seal plate vertically actuatable towards the first process chamber;
a first load lock chamber coupled to the housing above the first swapper;
a second process chamber coupled to the housing above the second swapper;
a second seal plate disposed in the housing beneath the second process chamber the second seal plate vertically actuatable towards the second process chamber; and
a second load lock chamber coupled to the housing above the second swapper.

17. The processing system of claim 16, wherein a rotational path of the first swapper overlaps with a rotational path of the second swapper.

18. The processing system of claim 17, wherein the first arm of the first swapper is vertically offset from a second arm of the second swapper to allow simultaneously rotation of the first swapper and the second swapper.

19. The processing system of claim 16, further comprising a first set of lift pins disposed in the housing beneath the first load lock.

20. The processing system of claim 19, wherein the first load lock comprises a vertically actuatable lid for ingress and egress of substrates.
